(19) United States
(12) Patent Application Publication
(10) Pub. No.: US 2016/0313408 A1
(43) Pub. Date: Oct. 27, 2016

(54) MAGNETIC MEASURING DEVICE

(71) Applicant: Renesas Electronics Corporation, Tokyo (JP)

(72) Inventors: Yuji HATANO, Tokyo (JP); Jun UENO, Tokyo (JP); Takashi YOSHINO, Tokyo (JP)

(21) Appl. No.: 15/098,136

(22) Filed: Apr. 13, 2016

(30) Foreign Application Priority Data
Apr. 21, 2015 (JP) 2015-086808

(51) Int. Cl. G01R 33/032; G01N 21/64

(52) U.S. Cl. CPC G01R 33/032; G01N 21/64; G01N 21/6456; G01N 2201/06113; G01N 2201/062

(57) ABSTRACT

A magnetic measuring device can be downsized. The magnetic measuring device includes a diamond crystal, a microwave source, a light source array/microwave circuit chip, an image sensor, and a signal controller. The diamond crystal contains a plurality of nitrogen-vacancy pairs. The microwave source generates the microwave that is irradiated to the diamond crystal. The microwave circuit unit in the light source array/microwave circuit chip irradiates the diamond crystal with the microwave. The light source array in the light source array/microwave circuit chip irradiates the diamond crystal with excitation light. The image sensor detects an intensity of fluorescent light generated from the diamond crystal. The signal controller performs image processing of a fluorescent image taken-in by the image sensor, and controls operations of the light source array/microwave circuit chip and the microwave source. The light source array/microwave circuit chip is provided on a first surface side of the diamond crystal, and the image sensor is provided on a second surface side opposed to the first surface of the diamond crystal.

### CROSS-REFERENCE TO RELATED APPLICATION

The present application claims priority from Japanese Patent Application No. 2015-86808 filed on Apr. 21, 2015, the content of which is hereby incorporated by reference into this application.

### TECHNICAL FIELD OF THE INVENTION

The present invention relates to a magnetic measuring device. More particularly, the present invention relates to a technique effectively applied to magnetic field detection in an atmospheric air at a normal temperature using a nitrogen-vacancy pair of a diamond crystal.

### BACKGROUND OF THE INVENTION

A diamond crystal containing a nitrogen-vacancy pair has been proposed as a high sensitivity magnetic field measuring device which can be operated in an atmospheric air at a normal temperature (see, for example, C. Müller, X. Kong, J. -M. Cai, K. Melentijević, A. Stacey, M. Markham, D. Twitchen, J. Isoya, S. Pezzagna, J. Meijer, J. F. Du, M. B. Plenio, B. Naydenov, L. P. McGuinness & F. Jelezko, “Nuclear magnetic resonance spectroscopy with single spin sensitivity”, NATURE COMMUNICATIONS/5:4703/DOI: 10.1038/ncomms5703 (Non-Patent Document 1)).

This Non-Patent Document 1 shows that, while green laser light is used as a light source which irradiates a diamond crystal with excitation light, a period of a pulse train of a microwave with which the diamond crystal is irradiated is adjusted, so that an alternating magnetic field of the high frequency (RF) electromagnetic wave can be measured.

### SUMMARY OF THE INVENTION

The Non-Patent Document 1 described above shows a measurement result of the alternating magnetic field generated by magnetic resonance from atoms which are close to each other in several nm (nanometers) by using excitation light from the green laser light source to one NV center in the diamond crystal, that is, to the nitrogen-vacancy pair of the diamond crystal.

However, in order to detect a signal generated by the magnetic resonance from an object which is further distant away, it is required to improve the sensitivity by using an equalized fluorescent output from many NV centers. In that case, as illustrated in FIG. 2 of the Non-Patent Document 1, a technique is generally used, the technique of irradiating the surface of the diamond crystal with excitation light through an objective lens while the fluorescent output is detected by the same objective lens.

Then, in order to separate the excitation light and the fluorescent light, a dichroic mirror is used. However, in the dichroic mirror, an angle of about 45° is usually set with respect to an optical path. In order to measure the fluorescent output of many NV centers, the diamond crystal having a wide area is required.

Tis manner has such a problem that the dichroic mirror also has a wide area, which results in a large volume of the optical system. For example, in a wearable diagnostic device which can detect the information inside a living body by arranging the magnetic measuring devices on the body surface, a size of the device becomes large or becomes too large to be realistic.

A magnetic measuring device according to an embodiment detects a magnetic field intensity from a change of a fluorescent light intensity. The magnetic measuring device includes a diamond crystal, a microwave unit, a light source unit, an image sensor, a signal processing unit, and a control unit.

The diamond crystal includes a plurality of nitrogen-vacancy pairs. The microwave unit irradiates the diamond crystal with the microwave. The light source unit irradiates the diamond crystal with excitation light. The image sensor detects an intensity of the fluorescent light generated from the diamond crystal by using a plurality of pixels. The signal processing unit performs image processing of the fluorescent image captured by the image sensor. The control unit controls operations of the light source unit, the microwave unit, and the signal processing unit.

Then, the light source unit is provided on a first surface side of the diamond crystal, and the image sensor is provided on a second surface side opposed to the first surface of the diamond crystal.

Particularly, the diamond crystal is diamond fine powders. The diamond fine powders are arranged so as to correspond to the pixels included in the image sensor, respectively.

According to the embodiment described above, the magnetic measuring device can be downsized.

### BRIEF DESCRIPTIONS OF THE DRAWINGS

FIG. 1 is an explanatory diagram illustrating a configuration example in a magnetic measuring device according to a first embodiment;

FIG. 2 is an explanatory diagram illustrating a relation between an excitation light input surface and a fluorescent output surface in the magnetic measuring device studied by the present inventors;

FIG. 3 is an explanatory diagram illustrating a relation between the excitation light input surface and the fluorescent output surface in the magnetic measuring device of FIG. 1;

FIG. 4 is an explanatory diagram illustrating a principle of a noninvasive internal measurement by the magnetic measuring device of FIG. 1;

FIG. 5 is an explanatory diagram illustrating another configuration example in the magnetic measuring device of FIG. 1;

FIG. 6 is an explanatory diagram illustrating a configuration example in a magnetic measuring device according to a second embodiment;

FIG. 7 is an explanatory diagram illustrating a configuration example in a magnetic measuring device according to a third embodiment;

FIG. 8 is a plan view illustrating a configuration example in a light source array unit included in the magnetic measuring device of FIG. 7;

FIG. 9A is an explanatory diagram illustrating a configuration example in a spacer included in the light source array unit of FIG. 8;

FIG. 9B is an explanatory diagram illustrating a configuration example in a spacer included in the light source array unit of FIG. 8;

FIG. 10 is an explanatory diagram illustrating an example of a timing of magnetic resonance signal measurement in a noninvasive internal measurement device which uses a magnetic measuring device according to a fourth embodiment;

FIG. 11 is an explanatory diagram illustrating another example of a timing of the magnetic resonance signal measurement of FIG. 10;

FIG. 12 is an explanatory diagram illustrating a configuration example in the noninvasive internal measurement device which uses the magnetic measuring device according to the fourth embodiment;

FIG. 13 is an explanatory diagram illustrating an example of planar local heating based on a resonance magnetic field region set in an inclined magnetic field by the noninvasive internal measurement device illustrated in FIG. 12;

FIG. 14 is an explanatory diagram illustrating an example of spherical or semispherical local heating based on a resonance magnetic field region set in an inclined magnetic field by the noninvasive internal measurement device illustrated in FIG. 12; and

FIG. 15 is an explanatory diagram illustrating an example of columnar local heating based on a resonance magnetic field region set in an inclined magnetic field by the noninvasive internal measurement device illustrated in FIG. 12.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and others), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle.

Similarly, in the embodiments described below, when the shape of the components, positional relation thereof, and others are described, the substantially approximate and similar shapes and others are included therein unless otherwise stated or except the case where it is conceivable that they are apparently excluded in principle. The same goes for the numerical value and the range described above.

Also, the same components are denoted by the same reference symbols throughout the drawings for describing the embodiments, and the repetitive description thereof is omitted. Also, in some drawings used in the embodiments, hatching is used even in a plan view so as to make the drawings easy to see.

Hereinafter, embodiments will be described in detail.

<Summary>

In a magnetic measuring device according to an embodiment, when a magnetic signal from a sample which is distant from a diamond crystal is detected, a light source is arranged on a first surface side of the diamond crystal close to the sample. An image sensor is arranged on a second surface side opposed to the first surface of the diamond crystal. In this manner, a measuring system which does not require a dichroic mirror separating excitation light and fluorescent light is achieved.

When a magnetic signal from a sample which is distant from the diamond crystal is detected, a gap may be generated between the diamond crystal and the sample. For this reason, the light source which has a thin and planar surface is inserted into the gap. In addition, an optical filter which blocks the excitation light is inserted between the diamond crystal and the image sensor, so that only the fluorescent output is made to reach the image sensor.

### First Embodiment

<Configuration and Operation Example of Magnetic Measuring Device>

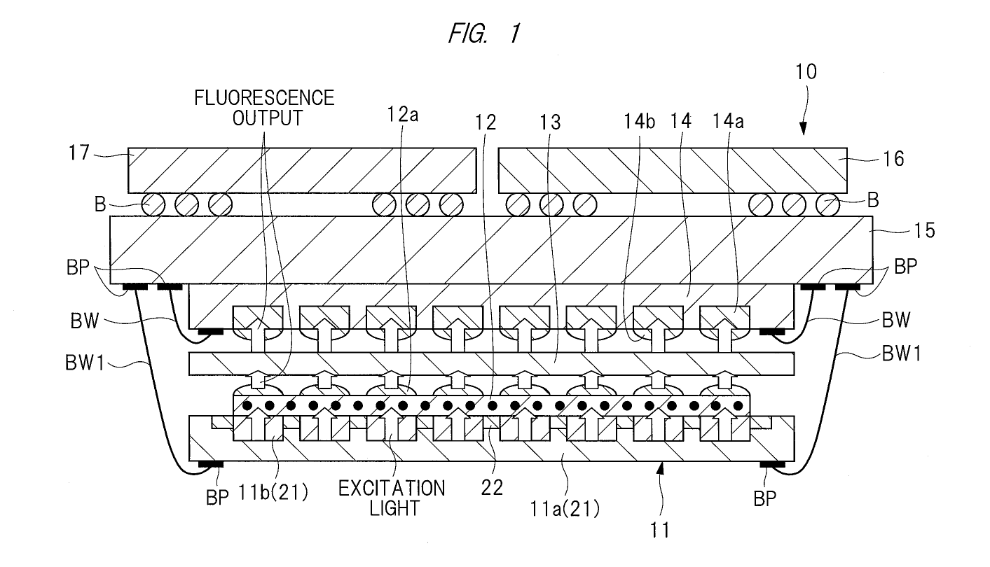

FIG. 1 is an explanatory diagram illustrating a configuration example in a magnetic measuring device 10 according to the present first embodiment.

A magnetic measuring device 10 is a biomagnetic detecting device used in a medical instrument such as a magnetoencephalograph, a magnetocardiograph, and a magnetomyograph which are biomagnetic measuring devices. For example, the magnetoencephalography noninvasively measures and analyzes a weak magnetic field generated along with nervous activity of the brain over the scalp.

The magnetic measuring device 10 is made up of such a configuration as a mirrorless module so that the magnetic measuring device 10 is thinned and downsized.

As illustrated in FIG. 1, the magnetic measuring device 10 is made up of a configuration provided with a light source array/microwave circuit chip 11, a diamond crystal 12, a filter thin film 13, an image sensor 14, a package substrate 15, a signal controller 16 and a microwave source 17. The microwave source 17 is a part of the microwave unit.

The diamond crystal 12 is stacked on the upper part of the light source array/microwave circuit chip 11 which includes the light source array 21 which is a light source unit and the microwave circuit unit 22 which is apart of the microwave unit, and the filter thin film 13 is provided above the diamond crystal 12 so as to have a certain gap therebetween.

The diamond crystal 12 has a plurality of nitrogen-vacancy pairs (illustrated by a black circle in the diamond crystal 12 in FIG. 1), in other words, NV centers, and the nitrogen-vacancy pairs are regularly arranged in a lattice form. Above the filter thin film 13, the image sensor 14 is provided so as to have a certain gap therebetween.

In other words, the light source array/microwave circuit chip 11 is stacked on a first surface of the diamond crystal 12, and the image sensor 14 is provided on a second surface which is a surface opposed to the first surface of the diamond crystal 12, that is, on the image sensor 14 side. Here, the first surface of the diamond crystal 12 is a surface on a side close to a sample SP illustrated in FIG. 3 described later.

The image sensor 14 is mounted on a rear surface of the package substrate 15. In addition, each of the signal controller 16 and the microwave source 17 which is a part of the microwave unit is mounted on a main surface of the package substrate 15. The signal controller 16 is made up of a control unit and a signal processing unit.

A bonding pad BP is formed on each of opposed two sides or four sides of the package substrate 15, the image sensor 14 and the light source array/microwave circuit chip 11.

The bonding pad BP of the package substrate 15 and the bonding pad BP of the image sensor 14 are connected with each other via a bonding wire BW. Similarly, the bonding pad BP of the package substrate 15 and the bonding pad BP of the light source array/microwave circuit chip 11 are connected with each other via a bonding wire BW1.

In addition, the microwave source 17 and the light source array/microwave circuit chip 11 are electrically connected with each other via the bonding pad BP of the light source array/microwave circuit chip 11, the bonding wire BW1, the bonding pad BP of the package substrate 15, not-illustrated wiring pattern formed on the package substrate 15 and a bump B such as a solder ball.

The light source array/microwave circuit chip 11 and the signal controller 16 are electrically connected with each other via the bonding pad BP of the light source array/microwave circuit chip 11, the bonding wire BW1, the bonding pad BP of the package substrate 15, a wiring pattern on the package substrate 15 and a bump B.

Similarly, the image sensor 14 and the signal controller 16 are electrically connected with each other via the bonding pad BP of the image sensor 14, the bonding wire BW, the bonding pad BP of the package substrate 15, a wiring pattern on the package substrate 15 and a bump B.

All of the light source array/microwave circuit chip 11, the diamond crystal 12, the filter thin film 13, the image sensor 14, the package substrate 15, the signal controller 16 and the microwave source 17 are sealed with, for example, a thermosetting resin or others, so that a not-illustrated package having a rectangular shape is formed.

The light source array/microwave circuit chip 11 has such a configuration that a light source array unit 21 and a microwave circuit unit 22 are formed in one chip. The light source array unit 21 has such a configuration that a light-emitting unit 11b is formed in an array form on a main surface of a substrate 11a such as a semiconductor substrate. The light-emitting unit 11b is made up of, for example, a light emitting diode (LED: Light Emitting Diode), and outputs excitation light having a wavelength of, for example, about 533 nm or shorter.

A light emitting operation in the light-emitting unit 11b is controlled by the signal controller 16. In addition, the microwave circuit unit 22 is formed in a gap of the light-emitting unit 11b on the main surface of the semiconductor substrate 11a. On the surface of the microwave circuit unit 22, a not-illustrated antenna is formed via a not-illustrated dielectric material.

The microwave circuit unit 22 applies a microwave electric current energized from the microwave source 17 to the above-described antenna to irradiate the diamond crystal 12 with the microwave. In this manner, a magnetic field of the microwave is generated in the periphery of the diamond crystal 12. Note that a frequency of the microwave outputted from the microwave source 17 is set by a control circuit of the signal controller 16 as described above.

The microwave circuit unit 22 generates microwave pulse trains at an interval which is a half cycle of the high-frequency (RF) electromagnetic wave used in the magnetic resonance measurement to be described later. A relation between a frequency “f” [GHz] of the microwave and a magnetostatic field B [unit T (Tesla)] which is applied to the diamond crystal 12 is required to satisfy “f=|B×28.07−2.87|[GHz]”. Here, “| 51” indicates an absolute value. Therefore, microwave pulses having a frequency different for each place of the light source array/microwave circuit chip 11 are generated.

The diamond crystal 12 is formed on the main surface of the light source array/microwave circuit chip 11. The diamond crystal 12 is a polycrystalline thin film deposited on the light source array/microwave circuit chip 11 by, for example, a CVD (Chemical Vapor Deposition) process which is one of vapor deposition processes.

On the upper surface of the diamond crystal 12, a micro lens 12a is formed. Each of the micro lens 12a and the light-emitting unit 11b is formed so as to correspond to the pixel 14a formed in the image sensor 14.

The excitation light generated by the light-emitting unit 11b is made to be incident onto the diamond crystal 12. The filter thin film 13 is an optical filter which totally reflects the excitation light focused by the micro lens 12a, and which inputs only a fluorescent output into the image sensor 14.

The image sensor 14 has such a configuration that the pixels 14a which are light receiving elements are regularly arranged in a lattice form. The image sensor 14 is a semiconductor sensor such as a CMOS image sensor (Complementary Metal Oxide Semiconductor Image Sensor), and takes a fluorescent image emitted from the diamond crystal 12 therein.

The micro lens 14b is formed at the position corresponding to each pixel 14a on the surface opposed to a mounting surface of the image sensor 14. The fluorescent output taken out by the filter thin film 13 is focused by the micro lens 14b and is taken into the pixel 14a of the image sensor 14.

The fluorescence image taken into the image sensor 14 is outputted to the signal controller 16. The signal controller 16 is made up of, for example, a microcomputer, etc., and includes each of not-illustrated signal processing circuit and control circuit.

Each of the signal controller 16 and the microwave source 17 described above is formed in, for example, a semiconductor chip or others. Here, an example of formation of the signal controller 16 and the above-described microwave source 17 by different semiconductor chips from each other has been described. However, they may be formed by one semiconductor chip.

The signal processing circuit included in the signal controller 16 performs image processing of the inputted fluorescent image. In addition, the control circuit included in the signal controller 16 supplies a timing signal to the image sensor 14, the light source array/microwave circuit chip 11 and the microwave source 17 to control the operations. In addition, the control circuit performs control for setting a microwave frequency to the microwave source 17.

In this manner, the magnetic measuring device 10 illustrated in FIG. 1, which has been modularized and thinned in a thickness direction, is particularly effectively applied to a wearable diagnostic device or others. The wearable diagnostic device has such a configuration that, for example, a plurality of magnetic measuring devices are attached to a cloth such as a shirt. Information inside a living body is detected by the arrangement of the magnetic measuring device 10 on a body surface of a human being.

The wearable diagnostic device in which the magnetic measuring device 10 are arranged densely on the body surface can be achieved by making the magnetic measuring device 10 so as to have a module configuration. In this manner, information on a deep unit in the living body can be detected with a high resolution.

In addition, since a light wearable diagnostic device with the less oppressive feeling can be achieved because of the small magnetic measuring device 10, a burden of a patient or others who wears the wearable diagnostic device can be reduced.

<Operation Principle of Magnetic Measuring Device>

Next, an operating principle in the magnetic measuring device 10 illustrated in FIG. 1 will be described.

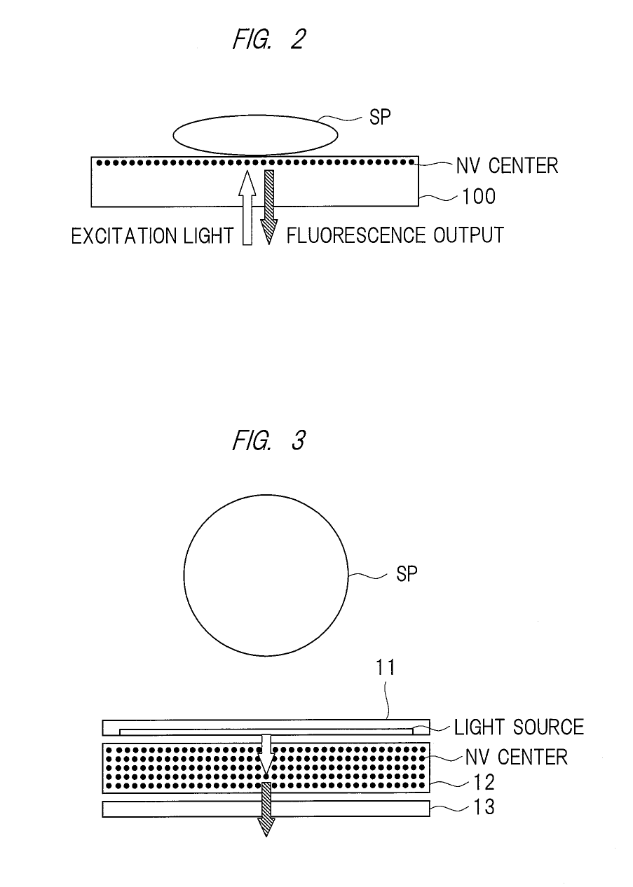

FIG. 2 is an explanatory diagram illustrating a relation between an excitation light input surface and a fluorescent output surface in the magnetic measuring device which has been studied by the present inventors, and FIG. 3 is an explanatory diagram illustrating a relation between the excitation light input surface and the fluorescent output surface in the magnetic measuring device 10 of FIG. 1.

FIG. 2 illustrates a positional relation between the sample SP and a diamond crystal 100 in a case of measurement of the sample SP close to the diamond crystal 100.

The NV centers, i.e., the nitrogen-vacancy pairs of the diamond crystal are generated in high density on a surface of the diamond crystal 100, the surface being close to the sample. In this manner, the sample can be measured in high resolution. The excitation light is inputted from an opposite side of the sample SP (in a direction indicated by a hollow arrow of FIG. 2) when viewed from the diamond crystal 100. The fluorescent output is outputted from an opposite side of the excitation light (in a direction indicated by a hatching arrow of FIG. 2). That is, it is required to input/output the excitation light and the fluorescent output from the same surface.

Meanwhile, FIG. 3 illustrates a positional relation between the sample and the diamond crystal in a case of measurement of the sample which is distant from the diamond crystal.

In this case, the NV centers are generated three-dimensionally in high density so as to distribute inside the diamond crystal 12 also in the thickness direction as illustrated. The magnetic signal from the sample SP which is distant from the diamond crystal 12 can be also measured by provision of a lot of NV centers.

Since the sample SP and the diamond crystal 12 are distant from each other, a thinly-surfaced light source can be arranged between the sample SP and the diamond crystal 12. Here, the excitation light is emitted from the light-emitting unit 11b of the light source array/microwave circuit chip 11. The excitation light is inputted from the above-described first surface of the diamond crystal 12 toward the opposed second surface.

In addition, from the second surface of the diamond crystal 12, the transmitted excitation light is outputted together with the fluorescent output. Here, only the fluorescent output can be taken out by providing the filter thin film 13 which is to be an excitation light reflecting filter on the second surface side of the diamond crystal 12. In this manner, the fluorescent output can be detected by the image sensor 14 of FIG. 1.

The filter thin film 13 is made up of a structure with, for example, a dielectric thin film stacked on a glass surface. Here, total reflection occurs under the condition of “t=λ/2/n/tan α” in assumptions that a refractive index of the dielectric thin film is “n”, that a thickness thereof is “t”, that a wavelength of the excitation light is “λ”, and that an incident angle of the excitation light with respect to the filter thin film 13 is “α”.

Since the excitation light is monochromatic light, λ is constant. As the dielectric material, a material which has high mechanical strength and a high refractive index such as titanium oxide (TᵢO₂) or aluminum oxide (Al₂O₃) is desired.

In this manner, when a magnetic signal from the sample SP which is distant from the diamond crystal 12 is detected, a gap can be generated between the diamond crystal 12 and the sample SP, and therefore, the light source array/microwave circuit chip 11 to be a light source can be provided in the gap.

In addition, only the fluorescent output generated by the diamond crystal 12 is made to reach the image sensor by providing the filter thin film 13, which cuts the excitation light, on the opposite side of the sample SP side of the diamond crystal 12.

As described above, the dichroic mirror or others which separates the excitation light and the fluorescent light is not required, so that the magnetic measuring device 10 can be downsized, more particularly, thinned.

In addition, as measurement using the magnetic measuring device 10 of FIG. 1, not only a magnetostatic field measurement which measures the magnetostatic field itself generated by a sample but also magnetic resonance measurement exist. In the magnetic resonance measurement, after applying a high frequency (RF) electromagnetic wave pulse having a specific frequency to a sample together with a magnetostatic field, a high frequency (RF) electromagnetic wave emitted is detected, or a high frequency (RF) electromagnetic wave emitted after a high frequency (RF) electromagnetic wave pulse train is applied is detected.

In the magnetic resonance measurement, energy of a high frequency (RF) electromagnetic wave absorbed or emitted by proton nucleus is used. In this case, it is known that the magnetostatic field “B0” and the high frequency (RF) electromagnetic wave frequency “F” have such a relation that “F/B0” is a constant value.

The proton is contained in water, and an organic body usually contains the water. Therefore, by the magnetic resonance signal, a distribution of the water, a chemical state thereof (e.g. a solute or a concentration), and a physical state thereof such as a temperature inside the organic body can be detected.

In this case, since only a portion where the relation “F/B0” becomes the above-described constant value in the sample resonates, a state inside the sample can be detected by an external magnetic measuring device by adjusting a magnetic field distribution.

In the magnetic resonance measurement, information of a deep portion in the living body can be detected with high resolution by using the wearable diagnostic device configured by densely arranging the above-described magnetic measuring device 10.

A temperature inside the organic body or others can be noninvasively measured in the same principle. This is because change in movement of a molecule depending on a temperature appears in relaxation time, chemical shift, a self-diffusion coefficient and others in the magnetic resonance signal.

<Principle of Noninvasive Internal Measurement>

Here, a noninvasive internal temperature measurement will be described as an application example of the magnetic measuring device.

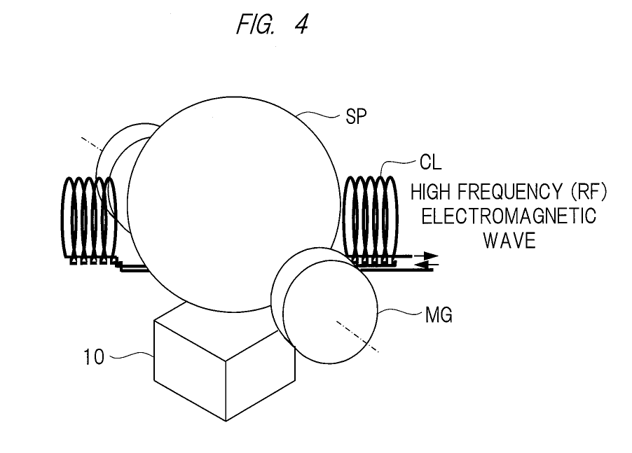

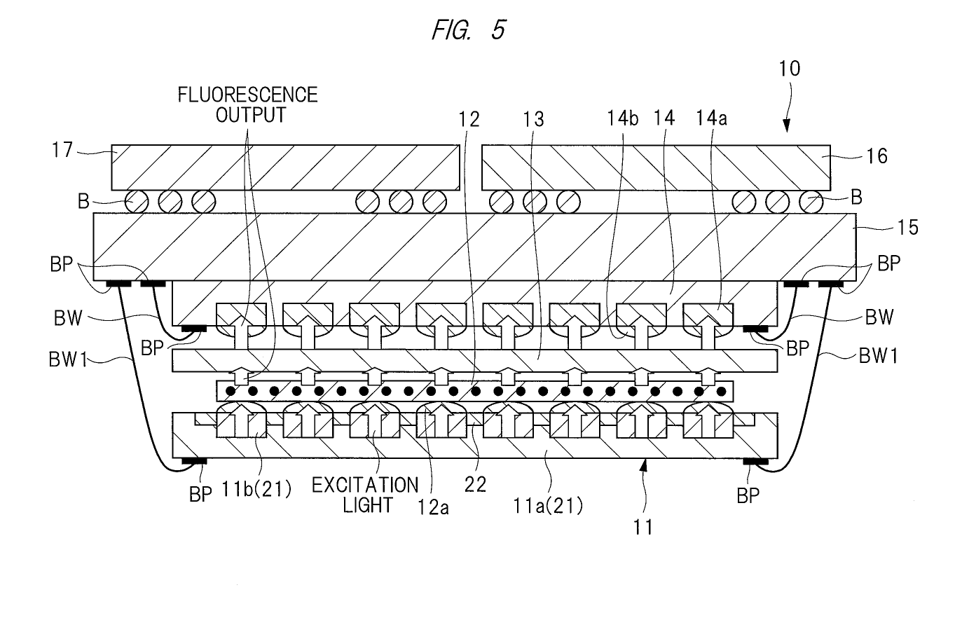

FIG. 4 is an explanatory diagram illustrating a principle of the noninvasive internal measurement by the magnetic measuring device 10 of FIG. 1.

The magnetostatic field is provided to the sample SP by a permanent magnet MG and the high frequency (RF) electromagnetic wave pulse is provided by a coil CL. After the high frequency (RF) electromagnetic wave pulse is provided, or after a pulse train of the high frequency (RF) electromagnetic wave is applied, the intensity of the high frequency (RF) electromagnetic wave outside the sample SP is measured by the magnetic measuring device 10.

The magnetic measuring device 10 can be arranged so as to be distant from the sample SP. A direct current magnetostatic field and the high frequency (RF) electromagnetic wave are applied in directions orthogonal to each other. For effectively detecting the high frequency (RF) electromagnetic wave from the sample SP, it is required to provide the magnetic measuring device 10 having a wide area.

Particularly in the case of the wide area, it is desired to provide the magnetic measuring device having a thin structure in a viewpoint of easiness of handling. Therefore, the magnetic measuring device 10 having the module configuration as illustrated in FIG. 1 becomes optimum.

<Other Configuration Example of Magnetic Measuring Device>

FIG. 5 is an explanatory diagram illustrating another configuration example in the magnetic measuring device 10 of FIG. 1.

In the magnetic measuring device 10 of FIG. 1, the diamond crystal 12 is deposited on the light source array/microwave circuit chip 11 by, for example, the CVD process. The magnetic measuring device 10 of FIG. 5 is different from the magnetic measuring device 10 of FIG. 1 in that the diamond crystal 12 is not deposited but a plate-shaped diamond crystal 12 is used. Also in the FIG. 5, note that the black circle in the diamond crystal 12 denotes the nitrogen-vacancy pair, and the nitrogen-vacancy pairs are arranged regularly in a lattice form in the diamond crystal 12.

In addition, in the case of the magnetic measuring device 10 illustrated in FIG. 1, the micro lens 12a is formed on the upper surface of the diamond crystal 12. However, in the case of the magnetic measuring device 10 of FIG. 5, this is formed on the upper surface of the light source array/microwave circuit chip 11. Note that the other configurations are the same as those of the magnetic measuring device 10 of FIG. 1, and therefore, descriptions thereof will be omitted.

In this manner, the magnetic measuring device 10 can be downsized, more particularly, thinned. In addition, the magnetic measuring device 10 is formed in a thin planar shape, and therefore, can be applied to various magnetic measurement techniques such as the above-described wearable diagnostic device and noninvasive internal temperature measurement.

### Second Embodiment

<Summary>

The above-described first embodiment has such a configuration that the magnetic measuring device contains the large area plate-shaped or deposited-on-a-chip diamond crystal. On the other hand, in the present second embodiment, a technique without the requirement of the large area diamond crystal will be described.

<Configuration Example of Magnetic Measuring Device>

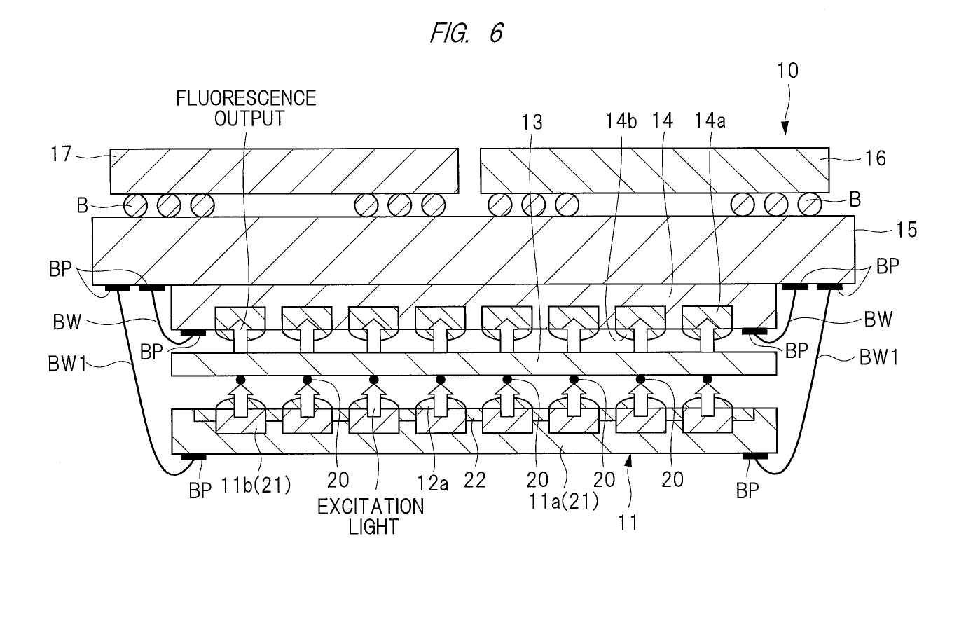

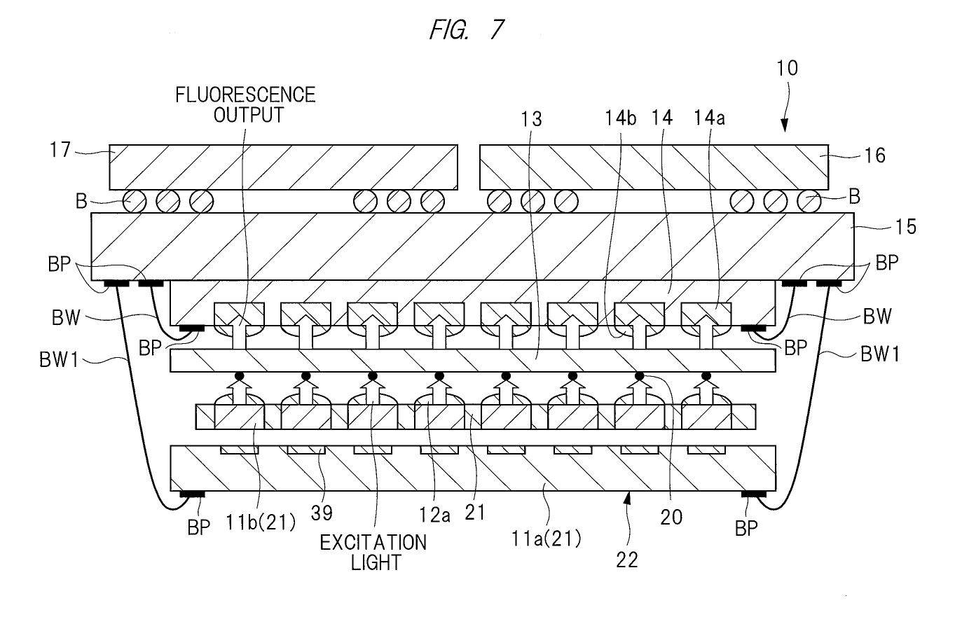

FIG. 6 is an explanatory diagram illustrating a configuration example in the magnetic measuring device 10 according to the present second embodiment.

The magnetic measuring device 10 illustrated in FIG. 6 is different from the magnetic measuring device 10 of FIG. 1 according to the first embodiment in that the large area diamond crystal 12 is not provided as described above. Therefore, the magnetic measuring device 10 of FIG. 6 is made up of the light source array/microwave circuit chip 11, the filter thin film 13, the image sensor 14, the package substrate 15, the signal controller 16 and the microwave source 17.

In addition, the micro lens 12a is formed on the surface of the light source array/microwave circuit chip 11 on the filter thin film 13 side. The micro lens 12a is provided at each position corresponding to the light-emitting unit 11b.

In place of the diamond crystal 12, diamond fine powders 20 are arranged regularly on the surface of the filter thin film 13 on the light source array/microwave circuit chip 11 side. The diamond fine powders 20 are in powder forms obtained by crushing the diamond crystal.

The diamond fine powder 20 has a nitrogen-vacancy pair (NV center), and is provided so as to correspond to the pixel 14a formed in the image sensor 14 as similar to the light-emitting unit 11b.

Between the filter thin film 13 and the light source array/microwave circuit chips 11, a not-illustrated insulation film made of silicon dioxide (SᵢO₂) or others is formed. The other configurations are the same as those in FIG. 1 according to the first embodiment, and therefore, descriptions thereof will be omitted.

<Operation Example of Magnetic Measuring Device>

The excitation light generated from the light-emitting unit 11b of the light source array/microwave circuit chip 11 is focused on the diamond fine powder 20 by the micro lens 12a, A fluorescent output generated by the diamond fine powder 20 transmits the filter thin film 13, and is focused on the image sensor 14 by the micro lens 14b formed on the image sensor 14. At this time, the excitation light does not reach the image sensor 14 because of being reflected by the filter thin film 13.

In a case of usage of a plate-shaped diamond crystal or others, the surface area of the magnetic measuring device is limited by the size of the diamond crystal. On the other hand, in the case of usage of the diamond fine powder in place of the diamond crystal, the diamond fine powder can be comparatively widely dispersed because of the fine powder.

In addition, the diamond fine powder is cheaper than the plate-shaped diamond crystal or others. Therefore, the magnetic measuring device 10 having a large surface area can be achieved at a low cost.

As described above, the magnetic measuring device 10 having a larger surface area can be achieved at a lower cost.

### Third Embodiment

<Summary>

The magnetic measuring device 10 in the above-described second embodiment has such a configuration that the light source array unit 21 and the microwave circuit unit 22 of the light source array/microwave circuit chip 11 are mounted on one chip. On the other hand, in the present third embodiment, a case that the light source array unit 21 and the microwave circuit unit 22 are made up on different chip from each other will be described.

<Configuration Example of Magnetic Measuring Device>

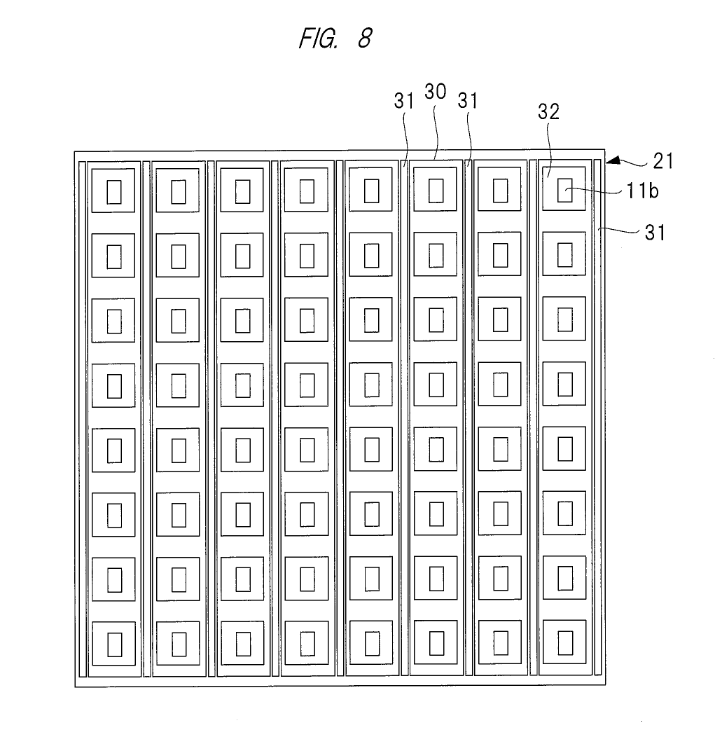

FIG. 7 is an explanatory diagram illustrating a configuration example in the magnetic measuring device 10 according to the present third embodiment.

The magnetic measuring device 10 of FIG. 7 is different from FIG. 6 of the second embodiment in two semiconductor chips of a semiconductor chip configuring the light source array unit 21 and a semiconductor chip configuring the microwave circuit unit 22 as described above.

Therefore, the magnetic measuring device 10 of FIG. 7 is configured by the light source array unit 21, the microwave circuit unit 22, the filter thin film 13, the image sensor 14, the package substrate 15, the signal controller 16 and the microwave source 17.

The magnetic measuring device 10 of FIG. 7 has such a configuration that the microwave circuit unit 22 is provided in the lowermost position, and that the light source array unit 21 is provided above the high frequency circuit unit. The light source array unit 21 has a configuration including the light-emitting unit 11b provided in an array form, and the light-emitting unit 11b is provided at each position corresponding to the pixel 14a included in the image sensor 14.

In addition, the micro lens 12a is formed on the surface of the light source array unit 21 on the filter thin film 13 side. The micro lens 12a is similarly provided so as to correspond to each pixel 14a.

The microwave circuit unit 22 has such a configuration including, for example, a plurality of microwave circuits 39 with a pair of a frequency conversion circuit and an antenna. In this case, each antenna is formed at the position corresponding to each region of the diamond fine powder 20, and each microwave circuit unit irradiates each region of the diamond fine powder 20 with a microwave having a frequency different for each region.

Between the light source array unit 21 and the microwave circuit unit 22, a not-illustrated insulation film made of silicon dioxide (SᵢO₂) or others is formed. The other configurations are the same as those in FIG. 6 according to the second embodiment, and therefore, descriptions thereof will be omitted.

<Configuration of Light Source Array Unit>

Next, a configuration of the light source array unit 21 will be described in more detail.

FIG. 8 is a plan view illustrating a configuration example in the light source array unit 21 included in the magnetic measuring device 10 of FIG. 7. FIG. 8 illustrates a plan view in the case of view of the light source array unit 21 from the filter thin film 13 side.

The light source array unit 21 is made up of a plurality of chip pieces 30 and a plurality of spacers 31 as illustrated in FIG. 8. The chip piece 30 has a rectangular shape, and a spacer 31 made of an insulation material is provided on aside surface of each chip piece 30 in the long-side direction. That is, the spacer 31 is sandwiched between the chip piece 30 and the chip piece 30.

In the chip piece 30, the light-emitting units 11b are linearly provided in the long-side direction of the chip piece 30 at equal intervals. As described above, the interval of the arrangement of the light-emitting unit 11b is substantially the same as an interval of the pixel 14a included in the image sensor 14.

The light-emitting unit 11b provided in the chip piece 30 is made up from, for example, a semiconductor laser or others. The semiconductor laser has such a structure provided with a luminous layer sandwiched between cladding layers 32 formed on a semiconductor wafer as a wafer process, and a laser light emission output is obtained from an end surface obtained by scribing the semiconductor wafer in a certain width.

Then, a light-emitting surface of the scribed chip, i.e., the chip piece 30 is arranged so as to be positioned on the filter thin film 13 side. In this manner, excitation light having a high output per unit area can be generated.

<Configuration Example of Spacer>

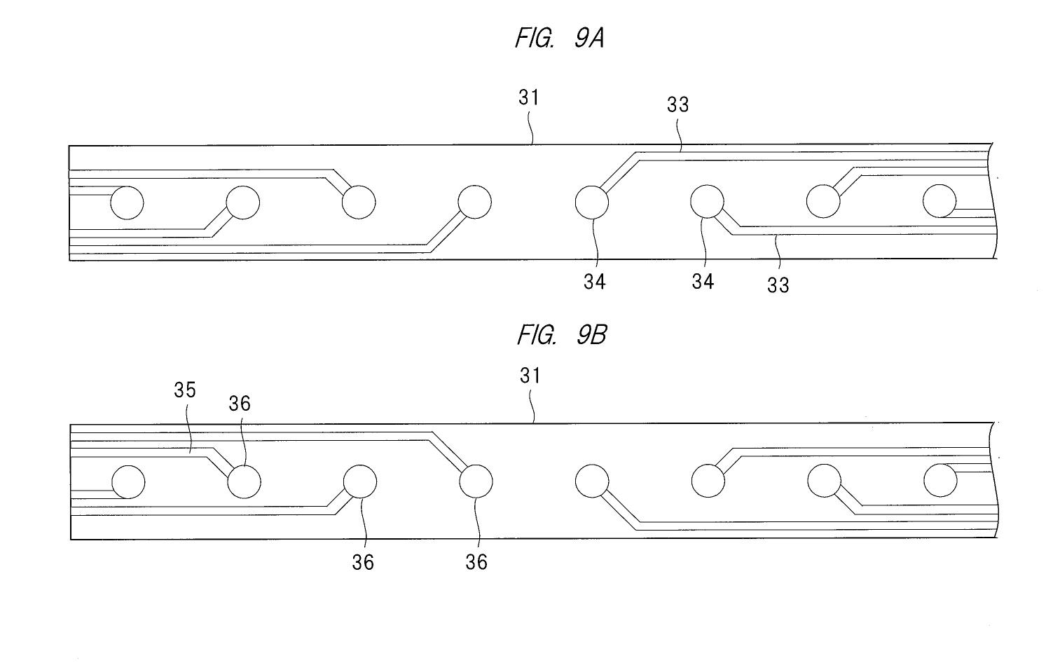

FIG. 9 is an explanatory diagram illustrating a configuration example in the spacer 31 included in the light source array unit 21 of FIG. 8.

FIG. 9A illustrates a configuration example in one side surface of the spacer 31, and FIG. 9B illustrates a configuration example in the other side surface of the spacer 31, the other side surface being opposed to the side surface illustrated in FIG. 9A.

As illustrated in FIG. 9A, wiring patterns 33 are formed in one side surface of the spacer 31. A cathode electrode 34 is formed at one end of the wiring patterns 33. In addition, as illustrated in FIG. 9B, wiring patterns 35 are formed in the other side surface of the spacer 31. An anode electrode 36 is formed at one end of the wiring pattern 35.

The cathode electrode 34 is connected to a cathode of the semiconductor laser which is the light-emitting unit 11b, and the anode electrode 36 is connected to an anode of the semiconductor laser.

On the side surface of the chip piece 30, the cathode electrode and the anode electrode although not illustrated are formed at the positions overlapped with the cathode electrode 34 and the anode electrode 36 which are formed in the spacer 31, respectively.

Then, the cathode electrode 34 of the spacer 31 and the cathode electrode of the chip piece 30 are contacted with the anode electrode 36 of the spacer 31 and the anode electrode of the chip piece 30, and are conducted therewith, respectively.

The cathode electrode provided in the chip piece 30 is connected to the cathode of the semiconductor laser which is the light-emitting unit 11b, and the anode electrode provided in the chip piece 30 is connected to the anode of the semiconductor laser.

In addition, to the wiring patterns 33 and 35 formed in the spacer 31, a power supply current which makes the semiconductor laser emit light is supplied. The supply and the supply timing of the power supply current are controlled by the signal controller 16 illustrated in FIG. 7.

The wiring pattern 33/the cathode electrode 34 and the wiring pattern 35/the anode electrode 36 are provided so as to individually correspond each to each semiconductor laser, so that the light emitting operation can be independently controlled by individually supplying the power supply current applied to the semiconductor laser. As described above, by individually controlling the light emitting of the semiconductor laser, the light emitting intensity can be corrected depending on a measurement condition such as a state of the sample.

As described above, the excitation light having a high output per unit area can be generated, and therefore, the magnetic measuring device 10 having higher performance can be achieved.

### Fourth Embodiment

<Summary>

In the present fourth embodiment, a measuring technique of a noninvasive internal measurement device using the magnetic measuring device 10 in the above-described first to third embodiments will be described.

<Timing Example of Magnetic Resonance Signal Measurement>

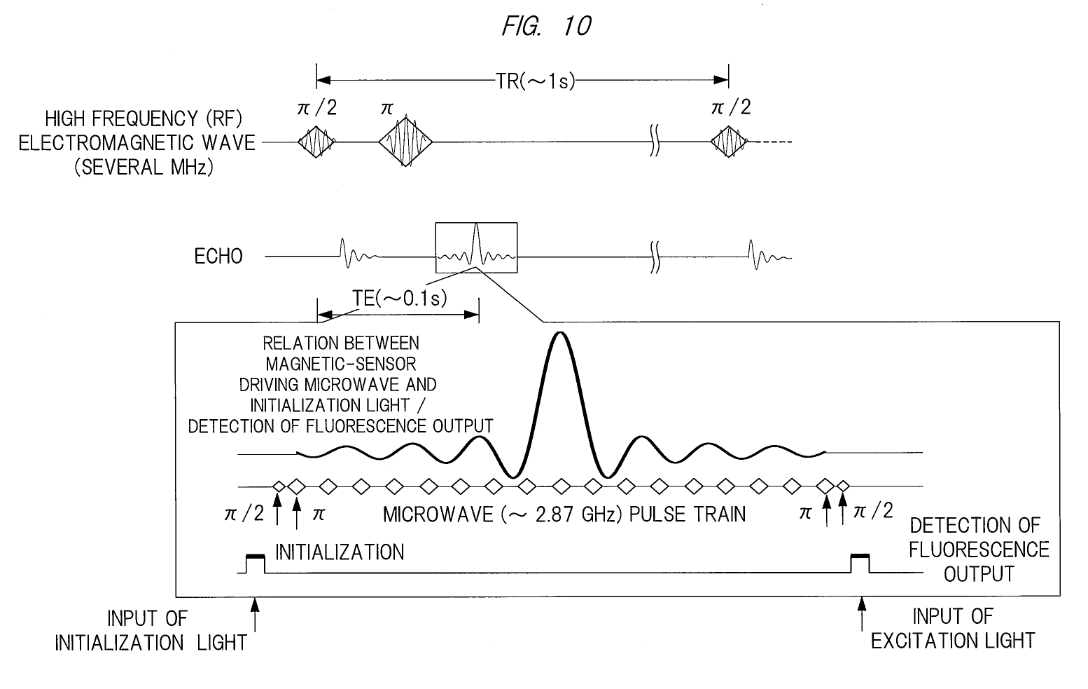

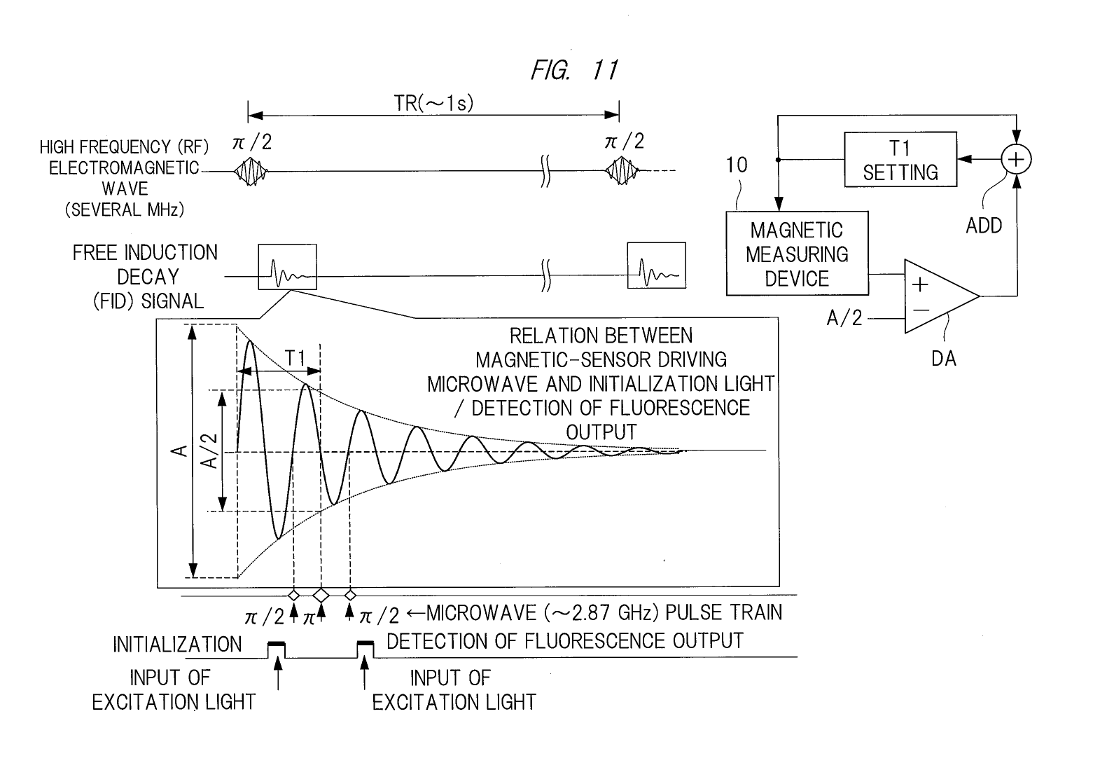

FIG. 10 is an explanatory diagram illustrating an example of a timing of magnetic resonance signal measurement in the noninvasive internal measurement device using the magnetic measuring device 10 according to the present fourth embodiment.

Since a relaxation time T1 of a water molecule is about several hundred milliseconds, π/2 pulse and π pulse trains of a high frequency (RF) electromagnetic wave are applied at a period of, for example, one second. The π pulse is a pulse to give energy enough to inverse a direction of precession motion of a proton atom which precesses under a magnetostatic field by 180°. The π/2 pulse is a pulse to give a half of the energy.

Here, an interval between the first π/2 pulse and the subsequent π pulse is assumed to be a relaxation time TE/2. Immediately after the first π/2 pulse, the emission of a magnetic resonance energy accumulated in a water molecule is started, and a Free Induction Decay (FID) signal is detected in the magnetic measuring device 10.

Furthermore, as illustrated in the lower side of FIG. 10, an echo signal is detected after TE/2 hours have elapsed from the π pulse. The FID signal and the echo signal have the same frequency as the high frequency (RF) electromagnetic wave, and the frequency F has a relation of F/B0=42.57 [MHz/Tesla] with the intensity B0 of the magnetostatic field in which the sample is located.

The microwave pulse train is applied from the microwave circuit chip to the diamond crystal with a ½ period of the high frequency (RF) electromagnetic wave. The frequency f of the microwave itself is also expressed by a function of the magnetostatic field intensity B [Tesla] in the position of the diamond crystal, which is “f=|B×28.07−2.87|” [GHz].

The initialization light is applied before the microwave pulse train, and the detection of the fluorescence output by using the image sensor is performed after the microwave pulse train. Each timing is different, and therefore, noise influences on the fluorescence output of the initialization light and the microwave pulse train can be avoided.

<Other Timing Example of Magnetic Resonance Signal Measurement>

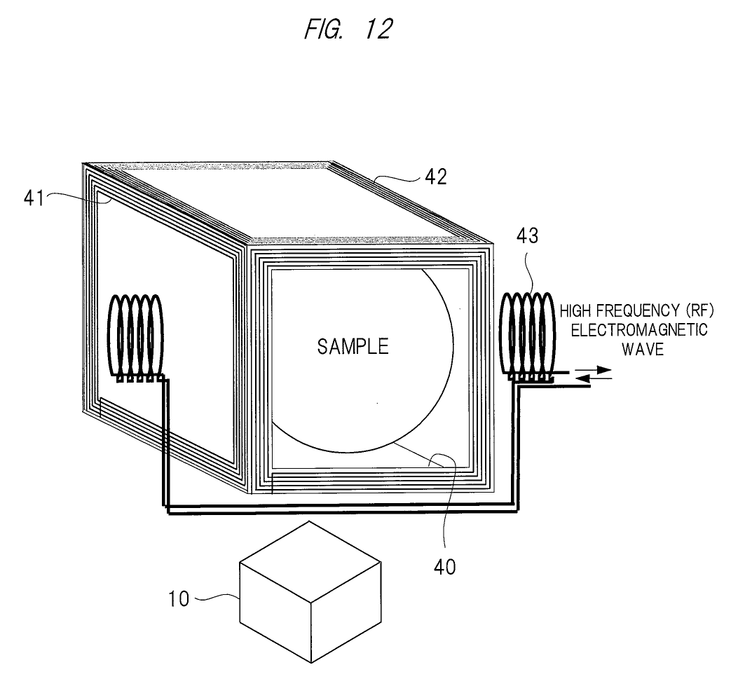

FIG. 11 is an explanatory diagram illustrating another example of a timing of the magnetic resonance signal measurement of FIG. 10. The FIG. 11 illustrates an example of the FID signal measurement in the magnetic resonance signal measurement.

The FID signal is attenuated by an elapsed time from the π/2 pulse. A time constant T1 of the attenuation reflects an internal state as the relaxation time. The right-hand side of FIG. 11 illustrates an example of efficient detection of the timing T1 by adjusting the timing T1 at which the sampling is to be performed without measuring the whole waveform, when a time in which an amplitude is attenuated to a specific value such as ½ is measured as the relaxation time T1.

A difference between the magnetic resonance signal measured by the magnetic measuring device 10 and, for example, ½ of the total amplitude “A” is taken by a differential amplifier DA. Then, the difference taken by the differential amplifier DA is added to the timing T1 by an adder ADD. In this manner, the timing T1 is converged to a timing at which the magnetic resonance signal becomes “A/2”. In this manner, the timing T1 can be efficiently measured.

<Specific Example of Noninvasive Internal Measurement Device>

Next, a specific example of the noninvasive internal measurement device configured by using the magnetic measuring device 10 in the above-described first to third embodiments will be described.

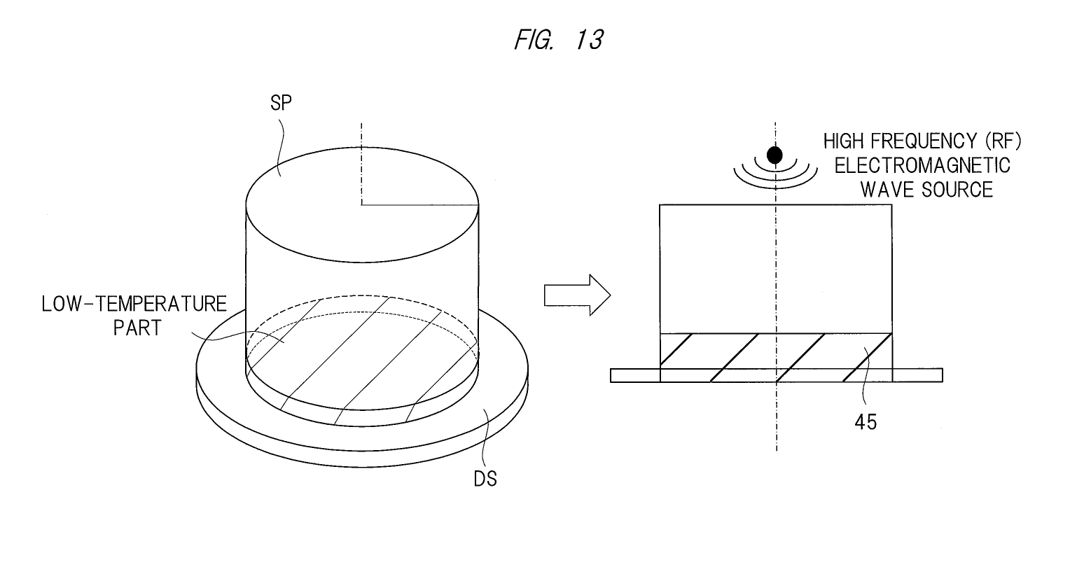

FIG. 12 is an explanatory diagram illustrating a configuration example in the noninvasive internal measurement device using the magnetic measuring device 10 according to the present fourth embodiment.

While the principle execution of the noninvasive internal measurement can be performed by the technique described in FIG. 3 according to the first embodiment, the magnetic field inside the sample SP can be inclined by making further the magnetic field controllable in three directions of the X direction, the Y direction and the Z direction.

In this manner, coordinates at which the magnetic resonance is generated in the sample SP can be controlled, so that a three-dimensional temperature distribution in the sample SP can be noninvasively obtained.

As illustrated, in the noninvasive internal measurement device, magnetic field generation coils 40 to 42 are arranged outside the sample SP to be a measurement object in respective three axis directions of the X direction, the Y direction and the Z direction. The inclined magnetic field is applied to the sample SP by applying appropriate direct currents to these magnetic field generation coils 40 to 42.

Protons in the cross section selected based a relation between the inclined magnetic field intensity and the RF frequency can be excited by applying the high frequency (RF) electromagnetic wave pulse by a high frequency (RF) electromagnetic wave pulse applying coil 43 while the inclined magnetic field is applied. The Free Induction Decay (FID) or echo signal generated by the excited proton is measured by the magnetic measuring device 10.

In the case of wearing the wearable diagnostic device described above, an MRI signal can be measured even if the inclined magnetic field is suppressed as much as being generable by the wound coil. In this manner, the whole MRI device can be downsized.

In addition, the noninvasive internal measurement device illustrated in FIG. 12 becomes also a heating device or others which locally heats the sample SP. This is because the high frequency (RF) electromagnetic wave is absorbed into coordinates at which the magnetic resonance is generated. In course of the heating, it is not required to apply the RF electromagnetic wave as a pulse, and the RF electromagnetic wave may be applied as a CW (Continuous Wave) wave. In this manner, a temperature distribution can be measured in the noninvasive internal measurement, so that the required portion can be heated. Such an application is useful to a medical application such as a hyperthermia, or an application to home appliances which perform cooking such as food heating.

Next, a locally heating technique by the noninvasive internal measurement device will be described.

FIG. 13 is an explanatory diagram illustrating an example of planar local heating based on a resonance magnetic field region set by the inclined magnetic field in the noninvasive internal measurement device illustrated in FIG. 12.

The left-hand side of FIG. 13A illustrates a perspective view of the locally-heated sample SP, and the sample SP is placed on, for example, a plate DS or others. In this case, the sample SP is an organic body such as food, and a region of a low temperature part illustrated by thin hatching is locally heated. In addition, the right-hand side of FIG. 13 illustrates a cross section of the sample SP illustrated in the left-hand side of FIG. 13.

In the local heating, only a certain region on the Z axis can be heated by setting a resonance magnetic field region 45 (region illustrated by thick hatching on the right-hand side of FIG. 13) by providing the uniform magnetic fields on the X and Y planes and providing the inclined magnetic field in the Z axis direction. In this manner, the region of the low temperature part illustrated by thin hatching of the sample SP illustrated on the left-hand side of FIG. 13 is locally heated.

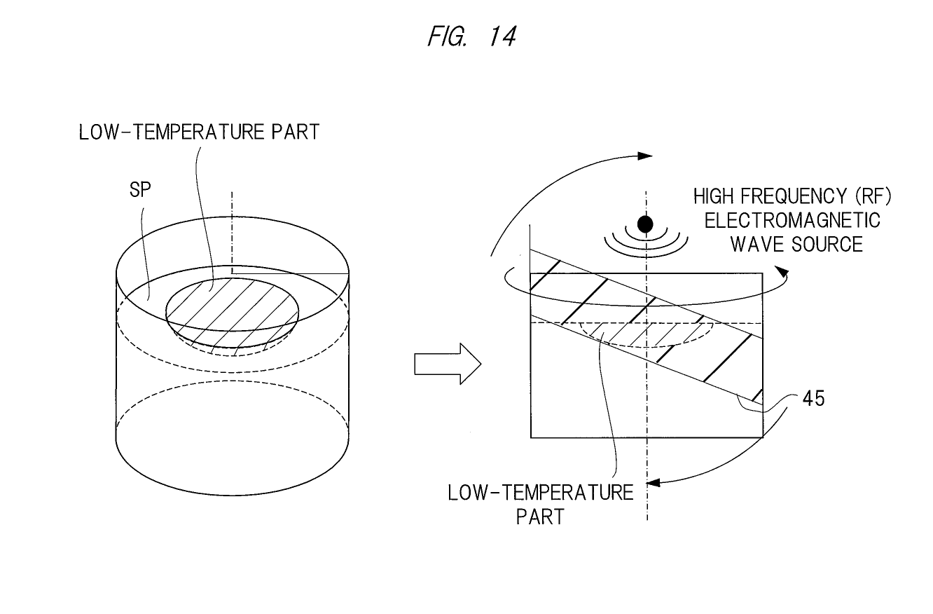

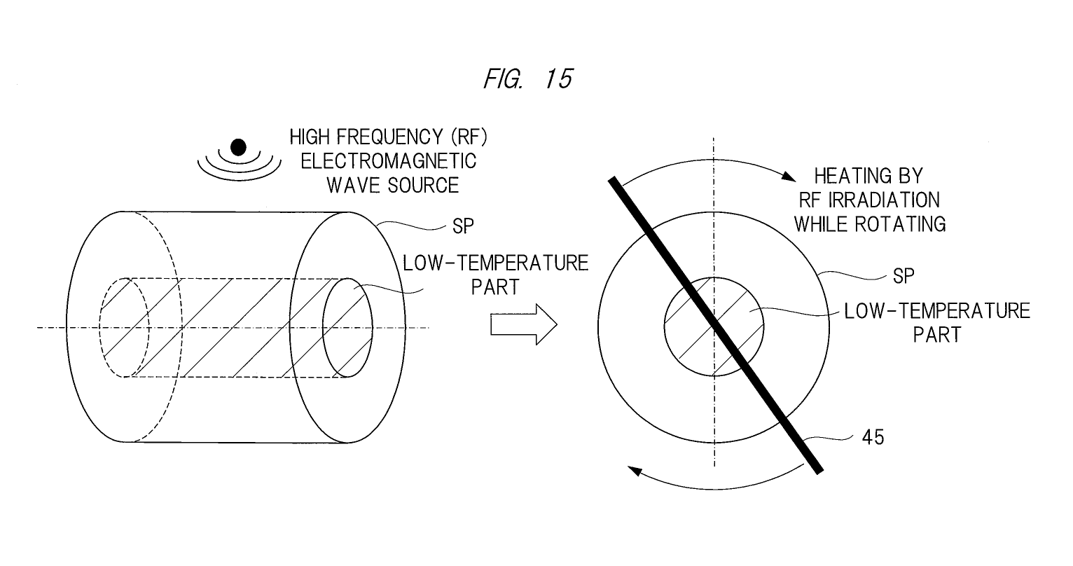

FIG. 14 is an explanatory diagram illustrating an example of spherical or semispherical local heating based on the resonance magnetic field region set by the inclined magnetic field by using the noninvasive internal measurement device illustrated in FIG. 12.

Also in FIG. 14, the left-hand side illustrates a perspective view of the locally-heated sample SP, and a cross section of the sample SP on the left-hand side of FIG. 14 is illustrated on the right-hand side of FIG. 14.

Also here, the sample SP is an organic body such as food, and a region of a low temperature part illustrated by thin hatching is locally heated. In addition, the right-hand side of FIG. 14 illustrates a cross section of the perspective view illustrated on the left-hand side of FIG. 14.

In this case, an inclination of the inclined magnetic field is provided in not only the Z axis direction but also the X axis direction and the Y axis direction. In this manner, a plane obtained by inclining a plane perpendicular to the Z axis toward the X axis direction or the Y axis direction becomes a plane where resonance is generated, i.e., the resonance magnetic field region 45 (region illustrated by thick hatching on the right-hand side of FIG. 14). By rotation of the magnetic field in the X axis direction and the Y axis direction around the Z axis in this state, the spherical or semispherical part inside the sample SP (region illustrated by thin hatching) can be heated.

A rotation speed of the magnetic field may be smaller than the time constant of the magnetic resonance signal. Here, it is not required to mechanically perform the rotation around the Z axis, and the rotation around the Z axis can be achieved by adjusting and varying the ratios in the time domain among the electric currents applied to the magnetic field generation coils 40, 41, and 42 of FIG. 12.

FIG. 15 is an explanatory diagram illustrating an example of columnar local heating based on the resonance magnetic field region set by the inclined magnetic field by using the noninvasive internal measurement device illustrated in FIG. 12. Also in FIG. 15, the left-hand side illustrates a perspective view of the locally-heated sample SP, and a cross section of the sample SP on the left-hand side of FIG. 15 is illustrated on the right-hand side of FIG. 15.

A plane which includes an axis in parallel to the axis of the columnar low temperature region to be heated and illustrated by the thin hatching on the left-hand side of FIG. 15 to make the magnetic field constant and where the magnetic resonance is caused, that is, the resonance magnetic field region 45 on the right-hand side of FIG. 15 is provided. In this state, the magnetic field is rotated around the axis of the resonance magnetic field region 45. Then, the periphery of the axis can be heated, so that the columnar local heating can be achieved.

As described above, the magnetic resonance measurement having a high sensitivity can be achieved at a low cost by using the magnetic measuring device 10 which has a small size and a high sensitivity.

In this manner, the noninvasive internal measurement device which is applicable to a medical application such as a hyperthermia, to a cooking tool or others can be downsized at a low cost.

In the foregoing, the invention made by the present inventors has been concretely described based on the embodiments. However, it is needless to say that the present invention is not limited to the foregoing embodiments and various modifications and alterations can be made within the scope of the present invention.

Note that the present invention is not limited to the above-described embodiments, and includes various modification examples. For example, the above-described embodiments have been explained for easily understanding the present invention, but are not always limited to the ones including all structures explained above.

Also, a part of the structure of one embodiment can be replaced with the structure of the other embodiment, and besides, the structure of the other embodiment can be added to the structure of one embodiment. Further, the other structure can be added to/eliminated from/replaced with a part of the structure of each embodiment.

What is claimed is:

1. A magnetic measuring device for detecting a magnetic field intensity from a change of a fluorescent light intensity, comprising:
a diamond crystal having a plurality of nitrogen-vacancy pairs;
a microwave unit irradiating the diamond crystal with a microwave;
a light source unit irradiating the diamond crystal with excitation light;
an image sensor detecting a fluorescent light intensity generated from the diamond crystal by a plurality of pixels;
a signal processing unit performing image processing of a fluorescent image taken-in by the image sensor; and
a control unit controlling an operation of the light source unit, the microwave unit, and the signal processing unit,
wherein the light source unit is provided on a first surface side of the diamond crystal, and
the image sensor is provided on a second surface side opposed to the first surface of the diamond crystal.

2. The magnetic measuring device according to claim 1,
wherein an optical filter which reflects excitation light which the light source unit irradiates with, and which makes fluorescent light generated from the diamond crystal reach the image sensor is included between the diamond crystal and the image sensor.

3. The magnetic measuring device according to claim 1,
wherein the diamond crystal is a polycrystalline thin film deposited by a vapor deposition process.

4. The magnetic measuring device according to claim 1,
wherein the diamond crystal is diamond fine powder, and
the diamond fine powder is arranged so as to correspond to each of the pixel included in the image sensor.

5. The magnetic measuring device according to claim 1,
wherein the light source unit includes a plurality of light-emitting units, and
each of a plurality of the light-emitting units is provided so as to correspond to the pixel included in the image sensor.

6. The magnetic measuring device according to claim 5,
wherein the light-emitting unit included in the light source unit is a semiconductor laser.

7. The magnetic measuring device according to claim 5,
wherein the control unit individually controls each light emission of the plurality of light-emitting units included in the light source unit.
